(19) United States
(12) Patent Application Publication
(10) Pub. No.: US 2013/0092533 A1
(43) Pub. Date: Apr. 18, 2013

(54) SPUTTER DEPOSITION APPARATUS

(71) Applicant: ULVAC, INC., Chigasaki-shi (JP)

(72) Inventors: Shigemitsu SATO, Chigasaki-shi (JP); Tetsuhiro OHNO, Chigasaki-shi (JP); Tatsunori ISOBE, Sammu-shi (JP); Tomokazu SUDA, Sammu-shi (JP)

(73) Assignee: ULVAC, INC., Chigasaki-shi (JP)

(21) Appl. No.: 13/688,753

(22) Filed: Nov. 29, 2012

Related U.S. Application Data
(63) Continuation of application No. PCT/JP2011/062667, filed on Jun. 2, 2011.

(30) Foreign Application Priority Data
Jun. 3, 2010 (JP) 2010-128344

(51) Int. Cl. C23C 14/35

(52) U.S. Cl. CPC C23C 14/352
USPC 204/298.12

(57) ABSTRACT

A sputter deposition apparatus can sputter a wider surface area of a sputtering surface of a target in comparison to an area that could be sputtered by a conventional apparatus. An adhesion-preventing member surrounding the outer periphery of a sputtering surface of a target made of a metal material is formed by insulating ceramic. The target is sputtered while moving a magnet device between a position where the entire outer periphery of an outer peripheral magnet is on the inside of the outer periphery of the sputtering surface and another position where a part of the outer periphery of the outer peripheral magnet protrudes out to the outside of the outer periphery of the sputtering surface.

This application is a continuation of International Application No. PCT/JP2011/062667, filed on Jun. 2, 2011, which claims priority to Japan Patent Application No. 2010-128344, filed on Jun. 3, 2010. The contents of the prior applications are herein incorporated by reference in their entireties.

### BACKGROUND

The present invention is generally related to a sputter deposition apparatus, and more particularly to a sputter deposition apparatus that uses a metal material as a target material.

Recently, a sputtering method is generally used as a method for forming a metallic thin film having a high melting point on a surface of an object to be film-formed having a large surface area.

FIG. 9 is a view showing an internal structure of a conventional sputter deposition apparatus 110.

The sputter deposition apparatus 110 includes a vacuum chamber 111 and a plurality of sputter units 120₁ to 120₄. The sputter units 120₁ to 120₄ have the same structure; and the following explanation uses the sputter unit associated with reference numeral 120₁ as a representative example. The sputter unit 120₁ includes a target 121₁ of a metal material, a backing plate 122₁, and a magnet device 126₁.

The target 121₁ is formed into a flat planar shape, which is smaller than the surface of the backing plate 122₁. The entire outer periphery of the target 121₁ is positioned on the inside of the outer periphery of the surface of the backing plate 122₁; and the target 121₁ is stacked upon and affixed to the backing plate 122₁ in a manner such that the peripheral edge of the surface of the backing plate 122₁ is exposed from the outer periphery of the target 121₁.

The magnet device 126₁ is disposed on the rear surface side of the backing plate 122₁. The magnet device 126₁ includes a center magnet 127b₁ disposed linearly on a magnet fixing plate 127c₁ which is parallel to the backing plate 122₁, and an outer peripheral magnet 127a₁ which surrounds the center magnet 127b₁ in a ring shape at a predetermined distance from the peripheral edge of the center magnet 127b₁. The outer peripheral magnet 127a₁ and the center magnet 127b₁ are respectively disposed in a manner such that their magnetic poles of different polarities oppose the rear surface of the target 121₁.

A moving device 129 is disposed on the underside of the magnet device 126₁; and the magnet device 126₁ is attached to the moving device 129. The moving device 129 is configured to move the magnetic device 126₁ in a direction parallel to the rear surface of the target 121₁.

The overall structure of the sputter deposition apparatus 110 will now be explained. The backing plates 122₁ to 122₄ of the sputter units 120₁ to 120₄ are arranged in a line spaced apart from each other on a wall surface on inside the vacuum chamber 111. The backing plates 122₁ to 122₄ are attached to the wall surface of the vacuum chamber 111 via insulators 114, and electrically insulated with the vacuum chamber 111.

On the outside of the outer periphery of the backing plates 122₁ to 122₄, metallic adhesion-preventing members 125 are disposed upright at a distance from the outer periphery of the backing plates 122₁ to 122₄, and electrically connected to the vacuum chamber 111. The top ends of the adhesion-preventing members 125 are bent at a right angle toward the outer peripheries of the targets 121₁ to 121₄ so as to cover the peripheral edges of the backing plates 122₁ to 122₄, and surround the surfaces of the targets 121₁ to 124₄ in a ring shape. Portions on the surface of the targets 121₁ to 121₄, which are exposed in the inner periphery of the ring of the adhesion-preventing members 125, are referred to as sputtering surfaces.

A vacuum evacuation device 112 is connected to an exhaust opening of the vacuum chamber 111 to evacuate the inside of the vacuum chamber 111. An object to be film-formed 131 is placed on an object holder 132, carried into the vacuum chamber 111, and held stationary at a position separated from and facing the sputtering surfaces of the targets 121₁ to 121₄. A gas introduction system 113 is connected to an inlet of the vacuum chamber 111 to introduce Ar gas, which is a sputtering gas, into the vacuum chamber 111.

A power source device 135 is electrically connected to the backing plates 122₁ to 122₄. When alternating current (AC) voltages that have reverse polarities are applied to two adjacent targets, the targets enter a state when one of the two adjacent targets is brought to a positive potential, while the other is brought to a negative potential. Electrical discharge is generated between the adjacent targets; and the Ar gas between the targets 121₁ to 121₄ and the object to be film-formed 131 is plasmatized.

Alternatively, the following constitution is also possible: the power source device 135 is electrically connected to the backing plates 122₁ to 122₄ and the object holder 132; AC voltages that have reverse polarities are applied to the targets 121₁ to 121₄ and the object to be film-formed 131; electrical discharge is generated between the targets 121₁ to 121₄ and the object to be film-formed 131; and the Ar gas between the targets 121₁ to 121₄ and the object to be film-formed 131 is plasmatized. In this case, the method can also be carried out using a single target.

The Ar ions inside the plasma are trapped in the magnetic fields formed by the magnet devices 126₁ to 126₄ on the surfaces of the targets 121₁ to 121₄, which are on the opposite side of the backing plates 122. When the targets 121₁ to 121₄ are brought to a negative potential, the Ar ions collide into the sputtering surfaces of the targets 121₁ to 121₄ and stricken off particles of metal material. A portion of the particles of metal material, which are stricken off, adheres to the surface of the object to be film-formed 131.

The magnetic fields generated on the targets 121₁ to 121₄ are non-uniform due to the structure of the magnet devices 126₁ to 126₄, as discussed above. Therefore, the Ar ions aggregate at portions of relatively high magnetic density and the targets 121₁ to 121₄ are scraped off at these portions more quickly compared to surrounding portions of relatively low magnetic density. In order to prevent the occurrence of such portions (erosions) where the targets 121₁ to 121₄ are locally scraped off as discussed above, sputtering is carried out while moving the magnet devices 126₁ to 126₄. However, when plasma trapped in the magnetic fields are in contact with the electrically-grounded adhesion-preventing members 125, an electric charge of the ions inside the plasma flows into ground potential through the adhesion-preventing members 125; and thus, the plasma disappears. Therefore, it is necessary to move the magnet devices 126₁ to 126₄ inside a range where the entire outer peripheries of the rings of the outer peripheral magnets 127a₁ to 127a₄ are positioned on the inside of the outer peripheries of the sputtering surfaces.

Thus, there has been a problem in that plasma does not reach the outer edges of the sputtering surfaces of the targets 121₁ to 121₄ and non-erosion areas which are not sputtered remain (see, for example, JPA No. 2008-274366).

### SUMMARY OF THE INVENTION

The present invention was created in order to solve the disadvantages of the above-discussed prior art, and an object thereof is to provide a sputter deposition apparatus which can sputter a wider surface area of a sputtering surface of a target than an area that could be sputtered by a conventional apparatus.

In order to solve the above problem, the present invention provides a sputter deposition apparatus including a vacuum chamber, a vacuum evacuation device that evacuates the inside of the vacuum chamber, a gas introduction system that introduces a sputtering gas into the vacuum chamber, a target that has a sputtering surface that is exposed within the vacuum chamber to be sputtered, a magnet device that is positioned on an underside of the sputtering surface of the target and is configured to be movable relative to the target, and a power source device that applies a voltage to the target. The magnet device has a center magnet that is disposed at an orientation to generate a magnetic field on the sputtering surface and an outer peripheral magnet that is disposed in a continuous shape on a periphery of the center magnet; the center magnet and the outer peripheral magnet are disposed so that their magnetic poles of mutually different polarities are oriented toward the sputtering surface; an adhesion-preventing member made of insulating ceramic is disposed at an end of the target, in which a surface including the sputtering surface on the surface of the target is discontinuous, so as to surround a periphery of the sputtering surface; and the magnet device moves between a position at which the entire outer periphery of the outer peripheral magnet is on the inside of the inner periphery of the adhesion-preventing member that surrounds the periphery of the sputtering surface and a position at which a portion of the outer periphery of the outer peripheral magnet protrudes to the outer periphery side beyond the inner periphery of the adhesion-preventing member that surrounds the periphery of the sputtering surface.

The present invention is a sputter deposition apparatus including a plurality of pairs of the target and the magnet device disposed on the underside of the sputtering surface of the target, in which the plurality of targets are arranged in a line spaced apart from each other, the sputtering surfaces are oriented toward an object to be film-formed carried into the vacuum chamber, and the power source device applies a voltage to at least one of the plurality of targets.

The present invention is a sputter deposition apparatus in which the target has a cylindrical shape having the sputtering surface which is a curved surface, and the magnet device moves parallel to the longitudinal direction of the target.

The present invention is a sputter deposition apparatus in which the magnet device that is disposed on the underside of the sputtering surface of at least one of the targets moves between a position at which the entire outer periphery of the outer peripheral magnet is on the inside of the inner periphery of the adhesion-preventing member that surrounds the periphery of the sputtering surface of the target and a position at which a portion of the outer periphery of the outer peripheral magnet protrudes out between the outside of the inner periphery of the adhesion-preventing member of the target and the inner periphery of the adhesion-preventing member that surrounds the periphery of the sputtering surface of another target adjacent to the target.

Since sputtering can be carried out on a wider surface area of a sputtering surface of a target compared to that of an area that could be sputtered by a conventional apparatus, the usage efficiency of the target can be improved and the life of the target can be extended.

In the case of a flat planar target, since the space between adjacent targets can be widened, the amount of target material to be used can be reduced; and thus, the cost can be reduced.

### BRIEF EXPLANATION OF THE DRAWINGS

FIG. 1 is a view of an internal structure of a first embodiment of a sputter deposition apparatus of the present invention.

FIG. 2 is a cross-sectional view along line A-A of FIG. 1 of the first embodiment of the sputter deposition apparatus of the present invention.

FIG. 3 is a cross-sectional view along line B-B of FIG. 1 of the first embodiment of the sputter deposition apparatus of the present invention.

FIG. 4 is a cross-sectional view along line A-A of FIG. 1 for explaining another structure of the first embodiment of the sputter deposition apparatus of the present invention.

FIG. 5(a) and FIG. 5(b) are schematic views showing cross-sections of a sputtering unit during sputtering.

FIG. 6 is a view of an internal structure of a second embodiment of a sputter deposition apparatus of the present invention.

FIG. 7 is a cross-sectional view along line C-C of FIG. 6 of the second embodiment of the sputter deposition apparatus of the present invention.

FIG. 8 is a cross-sectional view along line D-D of FIG. 6 of the second embodiment of the sputter deposition apparatus of the present invention.

FIG. 9 is a view of an internal structure of a conventional sputter deposition apparatus.

### DETAILED DESCRIPTION OF THE INVENTION

### <First Embodiment of the Sputter Deposition Apparatus of the Present Invention>

The structure of a first embodiment of the sputter deposition apparatus of the present invention will now be explained.

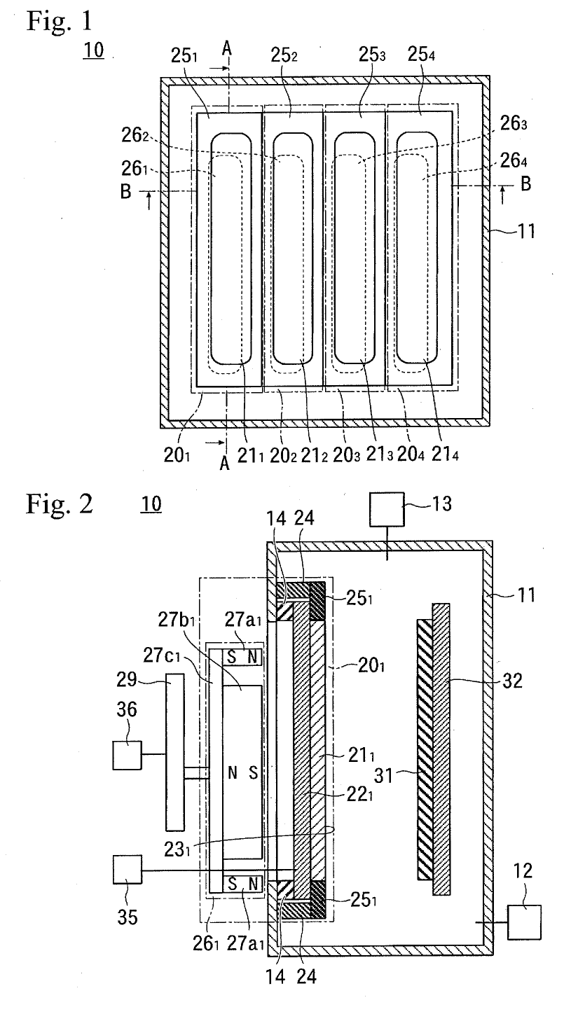

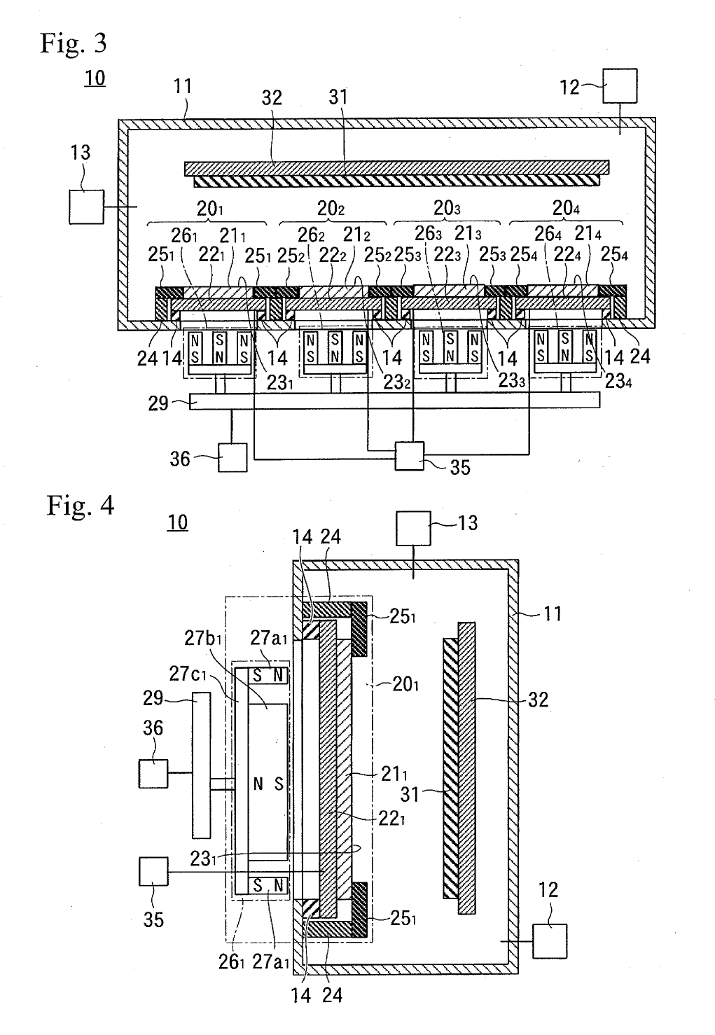

FIG. 1 is a view of an internal structure of a sputter deposition apparatus 10; FIG. 2 is a cross sectional view along line A-A of FIG. 1; and FIG. 3 is a cross sectional view along line B-B of FIG. 1.

The sputter deposition apparatus 10 includes a vacuum chamber 11 and a plurality of sputter units 20₁ to 20₄.

The structure of the sputter units 20₁ to 20₄ is the same. The following explanation uses the sputter unit associated with reference numeral 20₁ as a representative example.

The sputter unit 20₁ includes a target 21₁ made of a metal material having a sputtering surface 23₁ to be sputtered which is exposed within the vacuum chamber 11, a backing plate 22₁, an adhesion-preventing member 25₁ disposed at, the ends of the target 21₁, where a surface of the target 21₁ including the sputtering surface 23₁ is discontinuous, so as to surround the periphery of the sputtering surface 23₁, and a magnet device 26₁ which is disposed on an rear side of the sputtering surface 23₁ of the target 21₁ and is configured to be movable relative to the target 21₁.

The target 21₁ is formed into a flat planar shape, which is smaller than the surface of the backing plate 22₁. The entire outer periphery of the target 21₁ is positioned on the inside of the outer periphery of the backing plate 22₁; and the target 21₁ is stacked upon and affixed to the surface of the backing plate 22₁ in a manner such that the entire periphery at the peripheral edge of the backing plate 22₁ is exposed from the outer periphery of the target 21₁.

The adhesion-preventing member 25₁ is made of insulating ceramic and has a ring shape. A “ring shape” as used here refers to a shape surrounding the periphery of the sputtering surface 23₁ of the target 21₁, and does not necessarily mean a seamless circular ring. In other words, as long as it surrounds the periphery of the sputtering surface 23₁ of the target 21₁, any shape is sufficient; and the ring can include a plurality of parts and have a linear shape at a certain portion thereof.

As shown in FIG. 2, the outer periphery of the ring of the adhesion-preventing member 25₁ is larger than the outer periphery of the backing plate 22₁, and the inner periphery of the ring is the same as or larger than the outer periphery of the target 21₁.

The adhesion-preventing member 25₁ is disposed on the surface of the backing plate 22₁ on which the target 21₁ is fixed at a relative position in a manner such that the center of the ring of the adhesion-preventing member 25₁ overlaps with the center of the target 21₁, so as to cover the peripheral edge of the backing plate 22₁ exposed from the outer periphery of the target 21₁ and surround the outer periphery of the target 21₁ with the inner periphery of the ring of the adhesion-preventing member 25₁.

The inner periphery of the ring of the adhesion-preventing member 25₁ is preferably as small as possible so that plasma (to be explained later) does not invade into the gap between the inner periphery of the ring of the adhesion-preventing member 25₁ and the outer periphery of the target 21₁.

In reference to the surface which is closely adhered to the backing plate 22₁ among the two surfaces of the target 21₁ as the rear side surface and the opposite surface as the top surface, the entire top surface of the target 21₁ is exposed on the inside of the ring of the adhesion-preventing member 25₁, and the entire top surface of the target 21₁ forms the sputtering surface to be sputtered. Reference numeral 23₁ indicates the sputtering surface.

The adhesion-preventing member 25₁ of the present invention is not limited to a case in which the inner periphery of the ring of the adhesion-preventing member 25₁ is the same as or larger than the outer periphery of the target 21₁. As shown in FIG. 4, the present invention also includes a case in which the inner periphery of the ring of the adhesion-preventing member 25₁ is smaller than the outer periphery of the target 21₁. In this case, when the adhesion-preventing member 25₁ is disposed on the top surface of the target 21₁ as discussed above, the adhesion-preventing member 25₁ covers the peripheral edge of the target 21₁; and thus, the portion of the top surface of the target 21₁ which is exposed inside the ring of the adhesion-preventing member 25₁ is the sputtering surface 23₁ to be sputtered.

The magnet device 26₁ is disposed on the rear surface side of the backing plate 22₁; in other words, it is disposed on the rear surface side of the target 21₁.

The magnet device 26₁ has a center magnet 27b₁ which is disposed at an orientation to generate a magnetic field on the sputtering surface 23₁, and an outer peripheral magnet 27a₁ which is disposed in a continuous shape on the periphery of the center magnet 27b₁. Here, the center magnet 27b₁ is disposed linearly on a magnet fixing plate 27c₁ which is parallel to the backing plate 22₁; and the outer peripheral magnet 27a₁ surrounds the center magnet 27b₁ in a ring shape at a predetermined distance from the peripheral edge of the center magnet 27b₁ on the magnet fixing plate 27c₁.

In other words, the outer peripheral magnet 27a₁ has a ring shape, the center axis line of the ring of the outer peripheral magnet 27a₁ is oriented to vertically intersect the rear surface of the target 21₁, and the center magnet 27b₁ is disposed on the inside of the ring of the outer peripheral magnet 27a₁. A “ring shape” as used herein refers to a shape surrounding the periphery of the center magnet 27b₁, and does not necessarily mean a seamless circular ring. In other words, as long as it surrounds the periphery of center magnet 27b₁, any shape is sufficient, and the ring can include a plurality of parts and can have a linear shape at a certain portion thereof. The shape can also be a closed circular ring or a shape in which a circular ring is deformed while remaining closed.

The outer peripheral magnet 27a₁ and the center magnet 27b₁ are disposed in a manner such that their magnetic poles of different polarities face toward the rear surface of the target 21₁. In other words, the center magnet 27b₁ and the outer peripheral magnet 27a₁ are disposed in a manner such that their magnetic poles of reverse polarities are oriented toward the sputtering surface 23₁.

The overall structure of the sputter deposition apparatus 10 will now be explained. The backing plates 22₁ to 22₄ of the sputter units 20₁ to 20₄ are arranged in a line spaced apart from each other on a wall surface inside the vacuum chamber 11 so that the rear surfaces of the backing plates 22₁ to 22₄ faces toward the wall surface.

The backing plates 22₁ to 22₄ of the sputter units 20₁ to 20₄ are attached to the wall surface of the vacuum chamber 11 via columnar insulators 14; and the backing plates 22₁ to 22₄ of the sputter units 20₁ to 20₄ and the vacuum chamber 11 are electrically insulated.

Columnar support members 24 are disposed upright on the outside of the outer periphery of the backing plates 22₁ to 22₄ of the sputter units 20₁ to 20₄; and the adhesion-preventing members 25₁ to 25₄ of the sputter units 20₁ to 20₄ are fixed on the top ends of the support members 24.

If the support members 24 are electrically conductive, the support members 24 are spaced apart from the outer periphery of the backing plates 22₁ to 22₄ of the sputter units 20₁ to 20₄. The electrically-conductive support members 24 are electrically connected to the vacuum chamber 11. However, because the adhesion-preventing members 25₁ to 25₄ are insulative, the backing plates 22₁ to 22₄ and the vacuum chamber 11 are electrically insulated even if the adhesion-preventing members 25₁ to 25₄ make contact with the backing plates 22₁ to 22₄.

A power source device 35 is electrically connected to the backing plates 22₁ to 22₄ of the sputter units 20₁ to 20₄. The power source device 35 is configured to apply a voltage to at least one of the plurality of targets 21₁ to 21₄.

In the present embodiment, the power source device 35 is configured to apply AC voltages (herein) to the backing plates 22₁ to 22₄ of the sputter units 20₁ to 20₄ in a manner such that the AC voltages are shifted by half a period between two adjacent targets (a so-called AC sputtering method). When AC voltages that have reverse polarities are applied to two adjacent targets, the targets enter a state when one of the two adjacent targets is brought to a positive potential when the other is brought to a negative potential, and electrical discharge is generated between the adjacent targets. If the frequency of the AC voltages is in a range of 20 kHz to 70 kHz (20 kHz or greater to 70 kHz or less), the electrical discharge between the adjacent targets can be stabilized and maintained; and thus, a frequency in this range is preferable, and a frequency of 55 kHz is more preferable.

The power source device 35 of the present invention is not limited to a constitution in which it applies AC voltages to the backing plates 22₁ to 22₄ of the sputter units 20₁ to 20₄, and it can also be configured to apply pulsed negative voltages multiple times. In this case, the power source device 35 is configured to apply a negative voltage to one target among the two adjacent targets after completing application of a negative voltage to the other target and before beginning to apply the next negative voltage to the other target.

Alternatively, a power source device 35, which is an AC power source, can be electrically connected to the backing plates 22₁ to 22₄ of the sputter units 20₁ to 20₄ and to an object holder 32 (to be explained later), and AC voltages of reverse polarities can be applied to the targets 21₁ to 21₄ and object to be film-formed 31 (a so-called RF sputtering method).

Alternatively, in the present invention, the targets 21₁ to 21₄, which are made of electrically conductive materials, are sputtered to form a thin film made of an electrically conductive material on the surface of the object to be film-formed 31, as will be explained later. Therefore, a power source device 35, which is a direct current (DC) power source, can be electrically connected to the backing plates 22₁ to 22₄ of the sputter units 20₁ to 20₄ and an object holder 32; and negative voltages can be applied to the targets 21₁ to 21₄ and positive voltages can be applied to the object to be film-formed 31 (a so-called DC sputtering method).

In the RF sputtering method and the DC sputtering method, when the predetermined voltages are respectively applied to the backing plates 22₁ to 22₄ and the object holder 32 from the power source device 35, electrical discharge is generated between the targets 21₁ to 21₄ and the object to be film-formed 31. The RF sputtering method and the DC sputtering method can be carried out even in the case in which a single target is used; and thus, they are advantageous compared to the AC sputtering method.

A moving device 29, which is an XY stage, is disposed on the underside surface side of the magnet fixing plates 27c₁ to 27c₄ of the magnet devices 26₁ to 26₄ of the sputter units 20₁ to 20₄; and the magnet devices 26₁ to 26₄ are attached to the moving device 29. A control device 36 is connected to the moving device 29. When a control signal is received from the control device 36, the moving device 29 is configured to move the magnet devices 26₁ to 26₄ of the sputter units 20₁ to 20₄ in a direction parallel to the rear surface of the targets 21₁ to 21₄ of the sputter units 20₁ to 20₄.

The structure of the sputter units 20₁ to 20₄ is the same. The following explanation uses the sputter unit associated with reference numeral 20₁ as a representative example. The control device 36 is configured to move the magnet device 26₁ between a position where the entire outer periphery of the outer peripheral magnet 27a₁ is on the inside of the outer periphery of the sputtering surface 23₁ of the target 21₁ and another position where a part of the outer periphery of the outer peripheral magnet 27a₁ protrudes out to the outside of the outer periphery of the sputtering surface 23₁.

In other words, the magnet device 26₁ is configured to move between a position where the entire outer periphery of the outer peripheral magnet 27a₁ is on the inside of the inner periphery of the adhesion-preventing member 25₁ surrounding the periphery of the sputtering surface 23₁ and another position where a part of the outer periphery of the outer peripheral magnet 27a₁ protrudes to the outer periphery side beyond the inner periphery of the adhesion-preventing member 25₁ surrounding the periphery of the sputtering surface 23₁.

As explained later, when a part of the outer periphery of the outer peripheral magnet 27a₁ protrudes out to the outside of the outer periphery of the sputtering surface 23₁ during sputtering, plasma trapped in the magnetic field formed by the magnet device 26₁ is in contact with the adhesion-preventing member 25₁. However, in the sputter deposition apparatus 10 of the present invention, the adhesion-preventing member 25₁ is made of an insulating ceramic and the plasma is maintained; and thus, sputtering is continued and a wider surface area of the sputtering surface 23₁ is sputtered compared to a conventional apparatus. Therefore, the usage efficiency of the target 21₁ can be improved and the life of the target 21₁ can be extended.

During sputtering, when a portion of the outer periphery of the outer peripheral magnet 27a₁ protrudes out from the outer periphery of the sputtering surface 23₁ by a distance which is longer than a protruding minimum value to be explained later, sputtering is continuous from a point on the inside of the outer periphery of the sputtering surface 23₁ to an outer peripheral position.

Here, while repeatedly moving the magnet device 26₁, as described above, the control device 36 is configured to make the surface of the outer peripheral magnet 27a₁ face each point just under every point of the entire sputtering surface 23₁ of the target 21₁ at least once, and make the outer periphery of the outer peripheral magnet 27a₁ intersect every portion over the entire outer periphery of the sputtering surface 23₁ at least once.

Therefore, the entire inside of the outer periphery of the sputtering surface 23₁ is sputtered, and the usage efficiency of the target 21₁ is improved compared to a case in which a part of the outer periphery of the outer peripheral magnet 27a₁ protrudes out from only a part of the outer periphery of the sputtering surface 23₁.

In terms of the relationship between one sputter unit (for example, reference numeral 20₁) among the sputter units 20₁ to 20₄ and another sputter unit 20₂ which is adjacent, the control device 36 is configured to make the magnet device 26₁ of the one sputter unit 20₁ move between a position where the entire outer periphery of the outer peripheral magnet 27a₁ of the magnet device 26₁ is on the inside of the outer periphery of the sputtering surface 23₁ of the target 21₁ of the sputter unit 20₁ and another position where a part of the outer periphery of the outer peripheral magnet 27a₁ protrudes out between the outer periphery of the sputtering surface 23₁ and the outer periphery of the sputtering surface 23₂ of the target 21₂ of the other sputter unit 20₂ adjacent to the target 21₁.

In other words, if the area between the outer periphery of the sputtering surface 23₁ of the target 21₁ of the one sputter unit 20₁ and the outer periphery of the sputtering surface 23₂ of the target 21₂ of the other sputter unit 20₂ adjacent to the sputter unit 20₁ is referred to as the outside area, the control device 36 is configured to make the magnet device 26₁ of the one sputter unit 20₁ move between a position where the entire outer periphery of the outer peripheral magnet 27a₁ of the magnet device 26₁ is on the inside of the outer periphery of the sputtering surface 23₁ of the target 21₁ of the sputter unit 20₁ and another position where a part of the outer periphery of the outer peripheral magnet 27a₁ protrudes out to the outside area.

In other words, the magnet device 26₁ disposed on the rear side of the sputtering surface 23₁ of at least one target 21₁ is configured to move between a position where the entire outer periphery of the outer peripheral magnet 27a₁ is on the inside of the inner periphery of the adhesion-preventing member 25₁ surrounding the periphery of the sputtering surface 23₁ of the target 21₁ and another position where a part of the outer periphery of the outer peripheral magnet 27a₁ protrudes out between the outside of the inner periphery of the adhesion-preventing member 25₁ of the target 21₁ and the inner periphery of the adhesion-preventing member 25₂ surrounding the periphery of the sputtering surface 23₂ of the other target 21₂ adjacent to the target 21₁.

Therefore, in the present invention, if the size of the sputtering surfaces 23₁ to 23₄ of the targets 21₁ to 21₄ of the sputter units 20₁ to 20₄ is the same as in a conventional apparatus, and the width between the outer periphery of the erosion area to be sputtered of the sputtering surface 23₁ of the target 21₁ of one sputter unit (here, reference number 20₁) and the outer periphery of the erosion area of the sputtering surface 23₂ of the target 21₂ of another sputter unit 20₂ adjacent to the sputter unit 20, is the same as that in a conventional apparatus, the gaps between the outer peripheries of the adjacent targets 21₁ to 21₄ can be made wider than that in a conventional apparatus. Therefore, the amount of target material to be used can be reduced; and thus, the cost can be reduced.

An exhaust opening is provided on the wall surface of the vacuum chamber 11; and a vacuum evacuation device 12 is connected to the exhaust opening. The vacuum evacuation device 12 is configured to evacuate the inside of the vacuum chamber 11 from the exhaust opening.

An inlet is also provided on the wall surface of the vacuum chamber 11; and a gas introduction system 13 is connected to the inlet. The gas introduction system 13 has a sputtering gas source which releases sputtering gas; and is configured to be capable of introducing the sputtering gas into the vacuum chamber 11 from the inlet.

A sputter deposition method in which the sputter deposition apparatus 10 is used to form an Al thin film on the surface of the object to be film-formed 31 will now be explained.

First, the following explanation pertains to a step for measuring a protruding minimum value and a protruding maximum value, which are the minimum and maximum amounts that the parts of the outer peripheries of the outer peripheral magnets 27a₁ to 27a₄ of the magnet devices 26₁ to 26₄ of the sputter units 20₁ to 20₄ can protrude out from the outer peripheries of the sputtering surfaces 23₁ to 23₄ of the targets 21₁ to 21₄ of the sputter units 20₁ to 20₄.

In reference to FIGS. 2 and 3, the backing plates 22₁ to 22₄, to which the targets 21₁ to 21₄ of the sputter units 20₁ to 20₄ are attached, are carried into the vacuum chamber 11 and placed on the insulators 14. Here, Al is used for the targets 21₁ to 21₄ of the sputter units 20₁ to 20₄.

The adhesion-preventing members 25₁ to 25₄ of the sputter units 20₁ to 20₄ are fixed to the support members 24, and the sputtering surfaces 23₁ to 23₄ of the targets 21₁ to 21₄ of the sputter units 20₁ to 20₄ are exposed on the inside of the rings of the adhesion-preventing members 25₁ to 25₄ of the sputter units 20₁ to 20₄. Here, Al₂O₃ is used for the adhesion-preventing members 25₁ to 25₄ of the sputter units 20₁ to 20₄.

The inside of the vacuum chamber 11 is evacuated by the vacuum evacuation device 12; and the object holder 32, to which the object to be film-formed 31 is mounted, is not carried into the vacuum chamber 11. Subsequently, a vacuum ambience is maintained inside the vacuum chamber 11 by continuous evacuation.

The sputtering gas is introduced into the vacuum chamber 11 from the gas introduction system 13. Here, Ar gas is used for the sputtering gas.

The vacuum chamber 11 is brought to grounding potential. When AC voltages in the range of 20 kHz to 70 kHz are applied to the backing plates 22₁ to 22₄ of the sputter units 20₁ to 20₄ from the power source device 35, electrical discharge is generated between the adjacent targets 21₁ to 21₄, and the Ar gas above the targets 21₁ to 21₄ of the sputter units 20₁ to 20₄ is ionized and plasmatized.

Ar ions in the plasma are trapped in the magnetic fields formed by the magnet devices 26₁ to 26₄ of the sputter units 20₁ to 20₄. When negative voltages are applied to the backing plates 22₁ to 22₄ of the sputter units 20₁ to 20₄ from the power source device 35, the Ar ions collide into the sputtering surfaces 23₁ to 23₄ of the targets 21₁ to 21₄ on the backing plates 22₁ to 22₄ to which the negative voltages are applied, and Al particles are stricken off.

A portion of the Al particles which have been stricken off from the sputtering surfaces 23₁ to 23₄ of the targets 21₁ to 21₄ of the sputter units 20₁ to 20₄ adheres again to the sputtering surfaces 23₁ to 23₄ of the targets 21₁ to 21₄ of the sputter units 20₁ to 20₄.

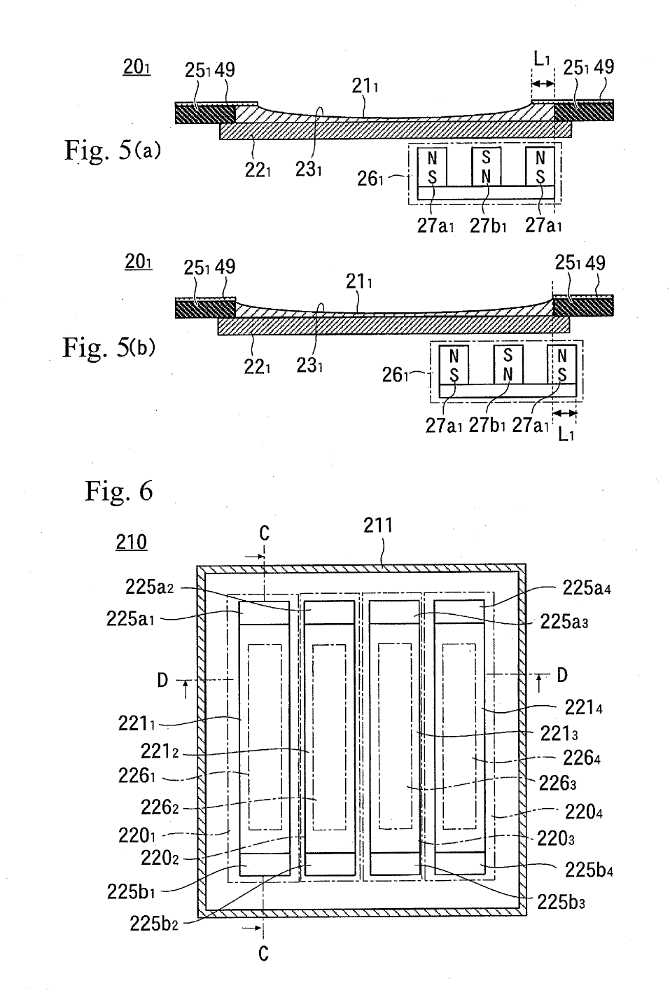

The state of the sputter units 20₁ to 20₄ during sputtering is the same. The following explanation uses the sputter unit associated with reference numeral 20₁ as a representative example. FIG. 5(a) is a schematic view showing a cross-sectional of the sputtering unit 20₁ during sputtering in the measuring step.

The sputtering surface 23₁ is sputtered while moving the magnet device 26₁ inside a movement range in which the entire outer periphery of the outer peripheral magnet 27a₁ is positioned inside of the outer periphery of the sputtering surface 23₁.

When sputtering is continued, the center portion of the sputtering surface 23₁ is scraped away by sputtering to a recessed shape. The area of the sputtering surface 23₁, which is scraped away by sputtering, is referred to as an erosion area. Al particles that adhere again accumulate at the non-erosion areas where areas outside of the erosion area on the sputtering surface 23₁ which are not sputtered. Reference numeral 49 indicates a thin film of accumulated Al.

The erosion area is scraped away until the outer periphery of the erosion area can be visually confirmed.

Next, the movement range of the magnet device 26₁ is gradually widened and the amount of the part of the outer periphery of the outer peripheral magnet 27a₁ which protrudes to the outside of the outer periphery of the sputtering surface 23₁ is gradually increased, while monitoring the gas composition and the pressure inside the vacuum chamber 11 during evacuation.

As the amount of the part of the outer periphery of the outer peripheral magnet 27a₁, which protrudes to the outside of the outer periphery of the sputtering surface 23₁, increases, the horizontal component of the magnetic field on the adhesion-preventing member 25₁ increases. Also, when the adhesion-preventing member 25₁ is scraped away by sputtering, the gas composition inside the vacuum chamber 11 changes during evacuation. When the sputtering of the adhesion-preventing member 25₁ has been confirmed from the change in the gas composition during evacuation inside the vacuum chamber 11, the amount of protrusion of the outer periphery of the outer peripheral magnet 27a₁ from the outer periphery of the sputtering surface 23₁ is measured.

In a producing step to be explained later, if the adhesion-preventing member 25₁ is scraped away by sputtering, particles of the adhesion-preventing member 25₁ adhere to the surface of the object to be film-formed 31, and the thin film formed on the surface of the object to be film-formed 31 becomes contaminated with impurities. Thus, the amount of protrusion measured here is the protruding maximum value.

In the case where the degree of hardness of the adhesion-preventing member 25₁ is too high to be sputtered (when a part of the outer periphery of the outer peripheral magnet 27a₁ protrudes to the inside of the sputtering surface 23₂ of the adjacent target 21₂ and the sputtering surface 23₂ of the adjacent target 21₂ is scraped away), the pressure inside the vacuum chamber 11 changes. When the sputtering of the sputtering surface 23₂ of the adjacent target 21₂ has been confirmed from the change in the pressure inside the vacuum chamber 11, the amount of protrusion of the outer periphery of the outer peripheral magnet 27a₁ from the outer periphery of the sputtering surface 23₁ is measured.

In a producing step to be explained later, if the sputtering surface 23₂ of the target 21₂ of one sputter unit 20₂ is scraped away by plasma trapped in the magnetic field of the magnet device 26₁ of the adjacent sputter unit 20₁, the planarity of the thin film formed on the surface of the object to be film-formed 31 decreases. Thus, the amount of protrusion measured here is the protruding maximum value.

Next, in reference to FIG. 3, the application of voltage to the backing plates 22₁ to 22₄ of the sputter units 20₁ to 20₄ is stopped, the introduction of Ar gas from the gas introduction system 13 is stopped, and sputtering is terminated.

The adhesion-preventing members 25₁ to 25₄ of the sputter units 20₁ to 20₄ are removed from the support members 24; and the targets 21₁ to 21₄ of the sputter units 20₁ to 20₄ are carried to the outside of the vacuum chamber 11 together with the backing plates 22₁ to 22₄.

In reference to FIG. 5(a), the outer periphery of the erosion area is visually confirmed, and an interval L₁ between the outer periphery of the erosion area which has been scraped away by sputtering on the sputtering surface 23₁ and the outer periphery of the sputtering surface 23₁ is found. Because inside of the interval L₁ from the outer periphery of the outer peripheral magnet 27a₁ is scraped away by sputtering, the interval L₁ found here is the protruding minimum value.

Next, the producing step will be explained in reference to FIG. 3. The backing plates 22₁ to 22₄ to which unused targets 21₁ to 21₄ of the sputter units 20₁ to 20₄ are attached are carried into the vacuum chamber 11 and placed on the insulators 14.

The adhesion-preventing members 25₁ to 25₄ of the sputter units 20₁ to 20₄ are fixed to the support members 24; and the sputtering surfaces 23₁ to 23₄ of the targets 21₁ to 21₄ of the sputter units 20₁ to 20₄ are exposed on the inside of the rings of the adhesion-preventing members 25₁ to 25₄.

The inside of the vacuum chamber 11 is evacuated by the vacuum evacuation device 12. Subsequently, a vacuum ambience is maintained inside the vacuum chamber 11 by continuous evacuation.

The object to be film-formed 31 is mounted on the object holder 32 and carried into the vacuum chamber 11, and then stopped at a position facing the sputtering surfaces 23₁ to 23₄ of the targets 21₁ to 21₄ of the sputter units 20₁ to 20₄.

Similar to the measuring step, the sputtering gas is introduced into the vacuum chamber 11 from the gas introduction system 13. AC voltages in the range of 20 kHz to 70 kHz are applied to the backing plates 22₁ to 22₄ of the sputter units 20₁ to 20₄ from the power source device 35; the Ar gas, which is the sputtering gas, between the targets 21₁ to 21₄ of the sputter units 20₁ to 20₄ and the object to be film-formed 31 is plasmatized; and the sputtering surfaces 23₁ to 23₄ of the targets 21₁ to 21₄ of the sputter units 20₁ to 20₄ are sputtered.

A portion of the Al particles that have been stricken off from the sputtering surfaces 23₁ to 23₄ of the targets 21₁ to 21₄ of the sputter units 20₁ to 20₄ adheres to the surface of the object to be film-formed 31; and an Al thin film is formed on the surface of the object to be film-formed 31.

The state of the sputter units 20₁ to 20₄ during sputtering is the same. The following explanation uses the sputter unit associated with reference numeral 20₁ as a representative example.

During sputtering, the magnet device 26₁ of the sputter unit 20₁ is made to repeatedly move between a position where the entire outer periphery of the outer peripheral magnet 27a₁ is on the inside of the outer periphery of the sputtering surface 23₁ of the target 21₁ of the sputter unit 20₁ and another position where a part of the outer periphery of the outer peripheral magnet 27a₁ protrudes out from the outer periphery of the sputtering surface 23₁.

Because the adhesion-preventing member 25₁ is made of an insulating material, while moving the magnet device 26₁ (as discussed above), the plasma trapped in the magnetic field of the magnet device 26₁ does not disappear even if the plasma is in contact with the adhesion-preventing member 25₁; and thus, sputtering can be continued. Therefore, a wider surface area of the sputtering surface 23₁ of the target 21₁ can be sputtered compared to a conventional apparatus.

FIG. 5(b) is a schematic view showing a cross-section of the sputtering unit 20₁ during sputtering in the producing step.

If a part of the outer periphery of the outer peripheral magnet 27a₁ protrudes out from each portion of the entire outer periphery of the sputtering surface 23₁ by a longer distance than the protruding minimum value L₁ found in the measuring step, the inside of the outer periphery of the sputtering surface 23₁, in its entirety, can be scraped off by sputtering.

Furthermore, if the distance which the outer periphery of the outer peripheral magnet 27a₁ protrudes from the outer periphery of the sputtering surface 23₁ is limited to a distance shorter than the protruding maximum value found in the measuring step, scraping off by sputtering of the adhesion-preventing member 25₁ can be prevented.

In reference to FIGS. 2 and 3, sputtering is continued for a predetermined amount of time while moving the magnet devices 26₁ to 26₄ of the sputter units 20₁ to 20₄, as discussed above, to form an Al thin film of a predetermined thickness on the surface of the object to be film-formed 31. Subsequently, the application of voltage to the backing plates 22₁ to 22₄ of the sputter units 20₁ to 20₄ is stopped; the introduction of Ar gas from the gas introduction system 13 is stopped; and sputtering is terminated.

The object to be film-formed 31 is carried to the outside of the vacuum chamber 11 together with the object holder 32 and sent to a post step. Subsequently, an object to be film-formed 31 upon which a film has not been deposited is placed on the object holder 32 and carried into the vacuum chamber 11; and sputter deposition according to the producing step, as discussed above, is repeated.

Alternatively, the object to be film-formed 31 on which a film has been deposited is removed from the object holder 32, carried to the outside of the vacuum chamber 11, and sent to a post step. Next, an object to be film-formed 31 upon which a film has not been deposited is carried into the vacuum chamber 11, placed on the object holder 32, and sputter deposition according to the producing step discussed above is repeated.

### <Second Embodiment of the Sputter Deposition Apparatus of the Present Invention>

The structure of a second embodiment of the sputter deposition apparatus of the present invention will now be explained.

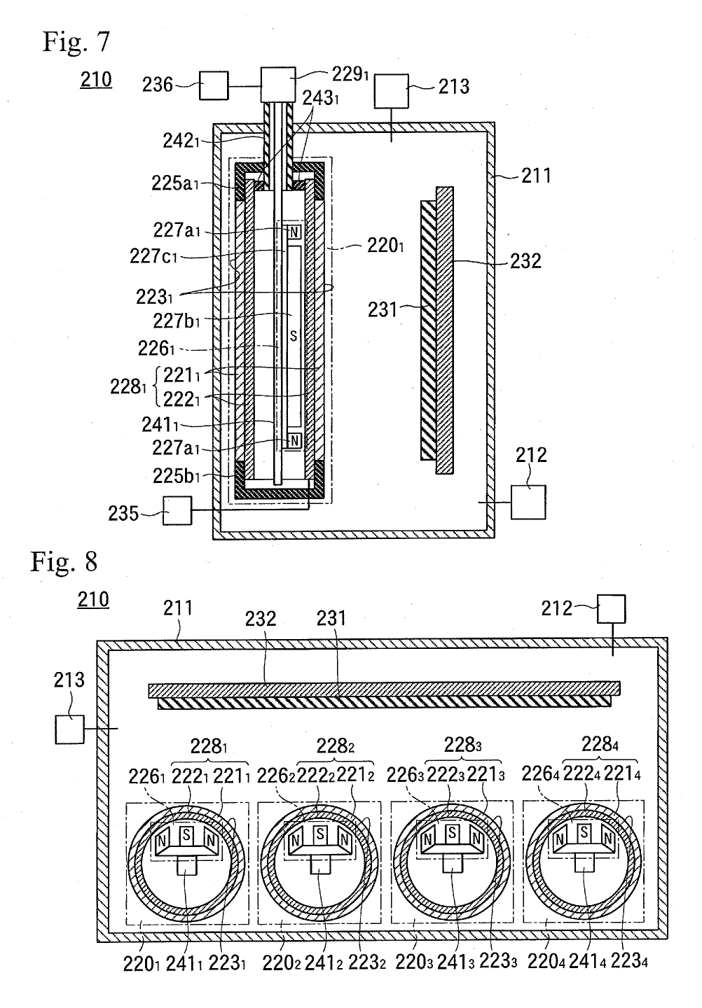

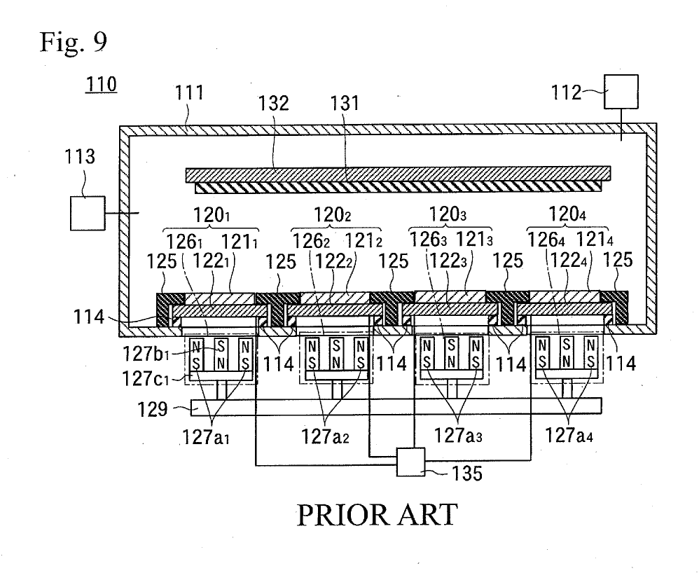

FIG. 6 is a view of an internal structure of a sputter deposition apparatus 210, FIG. 7 is a cross sectional view along line C-C of FIG. 6; and FIG. 8 is a cross sectional view along line D-D of FIG. 6.

The sputter deposition apparatus 210 includes a vacuum chamber 211 and a plurality of sputter units 220₁ to 220₄.

The structure of the sputter units 220₁ to 220₄ is the same. The following explanation uses the sputter unit associated with reference numeral 220₁ as a representative example.

The sputter unit 220₁ includes a target 221₁ made of a metal material having a sputtering surface 223₁ to be sputtered which is exposed inside the vacuum chamber 211, a backing plate 222₁, and a magnet device 226₁ disposed on an underside of the sputtering surface 223₁ of the target 221₁ and configured to be movable relative to the target 221₁.

Both the target 221₁ and the backing plate 222₁ have a cylindrical shape. Here, the length in the longitudinal direction of the target 221₁ is shorter than the length in the longitudinal direction of the backing plate 222₁; and the diameter of the inner periphery of the target 221₁ is the same or longer than the diameter of the outer periphery of the backing plate 222₁. The backing plate 222₁ is inserted into the inside of the target 221₁; the outer peripheral side surface of the backing plate 222₁ and the inner peripheral side surface of the target 221₁ are closely adhered to each other; and the backing plate 222₁ and the target 221₁ are electrically connected. One end and the other end of the backing plate 222₁ are respectively exposed from one end and the other end of the target 221₁.

Below, the target 221₁ and the backing plate 222₁ in a state in which the backing plate 222₁ is inserted into the inside of the target 221₁ will be collectively referred to as a target unit 228₁.

In reference to FIG. 7, a rotating cylinder 242₁ is inserted in an airtight manner into the wall surface at the ceiling side of the vacuum chamber 211. The diameter of the outer periphery of the rotating cylinder 242₁ is shorter than the diameter of the inner periphery of the backing plate 222₁; and a center line axis of the rotating cylinder 242₁ is oriented parallel to the vertical direction.

The target unit 228₁ is configured such that its center line axis matches the center line axis of the rotating cylinder 242₁; and the target unit 228₁ is disposed below the rotating cylinder 242₁. The bottom end of the rotating cylinder 242₁ is inserted into the inside of the backing plate 222₁; and the inside of the rotating cylinder 242₁ and the inside of the backing plate 222₁ are in communication.

The top end of the backing plate 222₁ is fixed to the bottom end of the rotating cylinder 242₁ via an insulator 243₁; and the backing plate 222₁ is electrically insulated with the rotating cylinder 242₁. The target unit 228₁ is spaced from the wall surface of the vacuum chamber 211 and is electrically insulated with the vacuum chamber 211.

A moving device 229₁ is attached to the top end of the rotating cylinder 242₁; and a control device 236 is connected to the moving device 229₁. The moving device 229₁ is configured to be capable of moving the rotating cylinder 242₁ together with the target unit 228₁ around the center line axis of the rotating cylinder 242₁ when it receives a control signal from the control device 236.

When an object to be film-formed 231 is disposed at a position facing the outer peripheral side surface of the target 221₁ of the target unit 228₁, and the rotating cylinder 242₁ is rotated by the moving device 229₁, a new surface of the outer peripheral side surface of the target 221₁ begins to face the object to be film-formed 231, and the entire outer peripheral side surface of the target 221₁ faces the object to be film-formed 231 during one rotation of the rotating cylinder 242₁.

A movement shaft 241₁ is inserted into the inside of the rotating cylinder 242₁ and the inside of the backing plate 222₁ across both the rotating cylinder 242₁ and the backing plate 222₁, and the axis line direction of the movement shaft 241₁ is oriented parallel to the vertical direction.

The magnet device 226₁ is attached to the movement shaft 241₁ at a portion on the inside of the backing plate 222₁.

The magnet device 226₁ has a center magnet 227b₁ which is disposed at an orientation in order to generate a magnetic field on the sputtering surface 223₁, an outer peripheral magnet 227a₁ that is disposed in a continuous shape on the periphery of the center magnet 227b₁, and a magnet fixing plate 227c₁. The magnet fixing plate 227c₁ is long and narrow; and the longitudinal direction of the magnet fixing plate 227c₁ is oriented parallel to the vertical direction.

The center magnet 227b₁ is disposed linearly on the magnet fixing plate 227c₁ parallel to the longitudinal direction of the magnet fixing plate 227c₁; and the outer peripheral magnet 227a₁ is disposed on the magnet fixing plate 227c₁ surrounding the center magnet 227b₁ in a ring shape at a distance from the peripheral edge of the center magnet 227b₁.

In other words, the outer peripheral magnet 227a₁ has a ring shape; the center axis line of the ring of the outer peripheral magnet 227a₁ is oriented to vertically intersect the inner peripheral side surface of the target 221₁; and the center magnet 227b₁ is disposed on the inside of the ring of the outer peripheral magnet 227a₁.

Magnetic poles of reverse polarities are respectively disposed on a portion of the outer peripheral magnet 227a₁ facing the magnet fixing plate 227c₁ and a portion of the center magnet 227b₁ facing the magnet fixing plate 227c₁. In other words, the center magnet 227b₁ and the outer peripheral magnet 227a₁ are disposed so that their magnetic poles of reverse polarities are facing toward the inner peripheral side surface of the backing plate 222₁.

On the outer peripheral side surface of the target 221₁, a magnetic field is formed on a rear surface side of a portion of the inner peripheral side surface of the target 221₁ facing the magnetic poles of the magnet device 226₁ via the backing plate 222₁. In other words, the center magnet 227b₁ and the outer peripheral magnet 227a₁ are disposed in a manner such that their magnetic poles of reverse polarities are oriented toward the sputtering surface 223₁.

The top end of the movement shaft 241₁ is connected to the moving device 229₁. The moving device 229₁ is configured to be capable of moving, in a reciprocating manner, the movement shaft 241₁ together with the magnet device 226₁ in the axis line direction of the movement shaft 241₁ (that is, parallel to the longitudinal direction of the target 221₁) when the moving device 229₁ receives a control signal from the control device 236.

When the magnet device 226₁ is moved by the moving device 229₁, the magnetic field formed by the magnet device 226₁ on the outer peripheral side surface of the target 221₁ moves reciprocally in a direction parallel to the longitudinal direction of the target 221₁.

The overall structure of the sputter deposition apparatus 210 will now be explained. The target units 228₁ to 228₄ of the sputter units 220₁ to 220₄ are arranged in a line spaced apart from each other on the inside of the vacuum chamber 211. One ends of the targets 221₁ to 221₄ of the sputter units 220₁ to 220₄ are aligned at the same height to each other; and the other ends of the targets 221₁ to 221₄ are also aligned at the same height to each other.

When the object to be film-formed 231 is arranged at a position facing the outer peripheral side surfaces of the targets 221₁ to 221₄, the intervals between the outer peripheral side surfaces of the targets 221₁ to 221₄ and the surface of the object to be film-formed 231 are aligned to be equivalent, and the magnetic poles of the magnet devices 226₁ to 226₄ disposed on the inside of the targets 221₁ to 221₄ are oriented to face the surface of the object to be film-formed 231.

A power source device 235 is electrically connected to the backing plates 222₁ to 222₄ of the sputter units 220₁ to 220₄. The power source device 235 is configured to apply a voltage to at least one of the plurality of targets 221₁ to 221₄.

In the present embodiment, the power source device 235 is configured to apply AC voltages to the backing plates 222₁ to 222₄ of the sputter units 220₁ to 220₄ in such a manner that the AC voltages are shifted by half a period between two adjacent targets. When AC voltages having reverse polarities are applied to two adjacent targets, the targets enter a state when one of the two adjacent targets is brought to a positive potential, the other is brought to a negative potential, and electrical discharge is generated between the adjacent targets. If the frequency of the AC voltages is in the range of 20 kHz to 70 kHz, the electrical discharge between the adjacent targets can be stabilized and maintained; and thus, a frequency in this range is preferable, although a frequency of 55 kHz is more preferable.

The power source device 235 of the present invention is not limited to a constitution in which it applies AC voltages to the backing plates 222₁ to 222₄ of the sputter units 220₁ to 220₄; and it can be configured to apply pulsed negative voltages multiple times. In this case, the power source device 235 is configured to apply a negative voltage to one target among the two adjacent targets after terminating application of a negative voltage to the other target and before beginning to apply the next negative voltage to the other target.

An exhaust opening is provided on the wall surface of the vacuum chamber 211; and a vacuum evacuation device 212 is connected to the exhaust opening. The vacuum evacuation device 212 is configured to evacuate the inside of the vacuum chamber 211 from the exhaust opening.

Furthermore, an inlet is provided on the wall surface of the vacuum chamber 211; and a gas introduction system 213 is connected to the inlet. The gas introduction system 213 has a sputtering gas source which releases sputtering gas, and is configured to be capable of introducing the sputtering gas into the vacuum chamber 211 from the inlet.

After the inside of the vacuum chamber 211 is evacuated by the vacuum evacuation device 212, sputtering gas is introduced into the vacuum chamber 211 from the gas introduction system 213. AC voltages are applied to the backing plates 222₁ to 222₄ of the sputter units 220₁ to 220₄ from the power source device 235 and an electrical discharge is generated between adjacent targets, the sputtering gas is plasmatized. Ions inside the plasma are trapped in the magnetic fields formed by the magnet devices 226₁ to 226₄; and when the targets 221₁ to 221₄ are brought to a negative potential, the ions collide into the surfaces of the targets 221₁ to 221₄ and stricken off particles of the targets 221₁ to 221₄.

The structure of the sputter units 220₁ to 220₄ is the same. The following explanation uses the sputter unit associated with reference numeral 220₁ as a representative example. The sputter unit 220₁ includes first and second adhesion-preventing members 225a₁ and 225b₁ disposed at the ends of the target 221₁, where the surface of the target 221₁ that includes the sputtering surface 223₁ is discontinuous, so as to surround the periphery of the sputtering surface 223₁.

The first and second adhesion-preventing members 225a₁ and 225b₁ are both made of insulating ceramic in a cylindrical shape. If the ends exposed at one end and the other end of the target 221₁ of the backing plate 222₁ are respectively referred to as the first and second ends, the length in the longitudinal direction of the first and second adhesion-preventing members 225a₁ and 225b₁ is longer than the length in the longitudinal direction of the first and second ends, and the diameter of the inner periphery of the first and second adhesion-preventing members 225a₁ and 225b₁ is the same or longer than the diameter of the outer periphery of the first and second ends.

The center axis line of the first and second adhesion-preventing members 225a₁ and 225b₁ matches the center axis line of the backing plate 222₁, and the first and second adhesion-preventing members 225a₁ and 225b₁ are arranged in such a manner that their inner peripheral side surfaces surround the outer peripheral side surfaces of the first and second ends of the backing plate 222₁.

Here, the first and second adhesion-preventing members 225a₁ and 225b₁ are respectively arranged on the outside of the space between one end and the other end of the target 221₁, and the entire outer peripheral side surface of the target 221₁ is exposed between the first and second adhesion-preventing members 225a₁ and 225b₁ to form the sputtering surface to be sputtered. Reference numeral 223₁ indicates the sputtering surface.

The gaps between the one end or the other end of the target 221₁ and the first and second adhesion-preventing members 225a₁ and 225b₁ are preferably as narrow as possible so that plasma (to be explained later) does not invade into the gaps between the one end or the other end of the target 221₁ and the first and second adhesion-preventing members 225a₁ and 225b₁.

The control device 236 is configured to send a control signal to the moving device 229₁ and move the magnet device 226₁ between a position where the entire outer periphery of the outer peripheral magnet 227a₁ is on the inside of the space between one end and the other end of the sputtering surface 223₁ of the target 221₁ and another position where a part of the outer periphery of the outer peripheral magnet 227a₁ protrudes out to the outside from at least one of the ends of the sputtering surface 223₁.

In other words, the magnet device 226₁ is configured to move between a position where the entire outer periphery of the outer peripheral magnet 227a₁ is on the inside of the inner periphery of the first and second adhesion-preventing members 225a₁ and 225b₁ surrounding the periphery of the sputtering surface 223₁ and another position where a part of the outer periphery of the outer peripheral magnet 227a₁ protrudes out to the outer periphery side beyond the inner periphery of the first and second adhesion-preventing members 225a₁ and 225b₁ surrounding the periphery of the sputtering surface 223₁. Here, the “inner periphery of the first and second adhesion-preventing members 225a₁ and 225b₁” means the edges on the sputtering surface 223₁ side of the first and second adhesion-preventing members 225a₁ and 225b₁.

When a part of the outer periphery of the outer peripheral magnet 227a₁ protrudes out toward the outside from at least one of the ends of the sputtering surface 223₁ during sputtering, plasma trapped in the magnetic field formed by the magnet device 226₁ is in contact with the first adhesion-preventing member 225a₁ or the second adhesion-preventing member 225b₁. However, because the first and second adhesion-preventing members 225a₁ and 225b₁ are made of an insulating ceramic, the plasma does not disappear even if the plasma is in contact with the first and second adhesion-preventing members 225a₁ and 225b₁. Thus, a wider surface area of the sputtering surface 223₁ is sputtered compared to a conventional apparatus. Therefore, the usage efficiency of the target 221₁ can be improved compared to a conventional art and the life of the target 221₁ can be extended.

Further, if a portion of the outer periphery of the outer peripheral magnet 227a₁ protrudes out from both one and the other ends of the sputtering surface 223₁ by a longer distance than the protruding minimum value (to be explained later) during sputtering, the sputtering surface 223₁ is sputtered continuously from one end to the other end. If the target 221₁ is simultaneously rotated around the center axis line by the moving device 229₁, the entire surface of the sputtering surface 223₁ is sputtered.

The present invention is not limited to a case in which the first and second adhesion-preventing members 225a₁ and 225b₁ are disposed outside of the space between the one end and the other end of the target 221₁; and the present invention includes a case in which one or both of the first and second adhesion-preventing members 225a₁ and 225b₁ are disposed to protrude toward the inside of the space between the one end and the other end of the target 221₁. In this case, the part of the outer peripheral side surface of the target 221₁ which is exposed between the first and second adhesion-preventing members 225a₁ and 225b₁ becomes the sputtering surface 223₁ to be sputtered.

Here, the first and second adhesion-preventing members 225a₁ and 225b₁ are respectively fixed to the backing plate 222₁; and when the backing plate 222₁ is rotated by the moving device 229₁, the first and second adhesion-preventing members 225a₁ and 225b₁ are also rotated together. The present invention also includes a case in which one or both of the first and second adhesion-preventing members 225a₁ and 225b₁ are not fixed to the backing plate 222₁ but rather, for example, fixed to the vacuum chamber 211, so that one or both of the first and second adhesion-preventing members 225a₁ and 225b₁ do not rotate even if the backing plate 222₁ is rotated around the center axis line.

A sputter deposition method in which the sputter deposition apparatus 210 is used to form an Al thin film on the surface of the object to be film-formed 231 will now be explained.

First, the following explanation pertains to a step for measuring a protruding minimum value and a protruding maximum value, which are the minimum and maximum amounts that the parts of the outer peripheries of the outer peripheral magnets 227a₁ to 227a₄ of the magnet devices 226₁ to 226₄ of the sputter units 220₁ to 220₄ can protrude out toward the outside of the spaces between the one end and the other end of the sputtering surfaces 223₁ to 223₄ of the targets 221₁ to 221₄ of the sputter units 220₁ to 220₄.

Here, Al is used for the targets 221₁ to 221₄ of the sputter units 220₁ to 220₄; and Al₂O₃ is used for the first and second adhesion-preventing members 225a₁ to 225a₄ and 225b₁ to 225b₄.

In reference to FIGS. 7 and 8, the inside of the vacuum chamber 211 is evacuated by the vacuum evacuation device 212 while the object to be film-formed 231 is not carried into the vacuum chamber 211. Subsequently, a vacuum ambience is maintained inside the vacuum chamber 211 by continuous evacuation. The sputtering gas is introduced into the vacuum chamber 211 from the gas introduction system 213. Here, Ar gas is used for the sputtering gas.

The vacuum chamber 211 is brought to ground potential. When AC voltages in the range of 20 kHz to 70 kHz are applied, as discussed above, to the backing plates 222₁ to 222₄ of the sputter units 220₁ to 220₄ from the power source device 235, electrical discharge is generated between the adjacent targets 221₁ to 221₄, and the Ar gas above the targets 221₁ to 221₄ of the sputter units 220₁ to 220₄ is ionized and plasmatized.

Ar ions in the plasma are trapped in the magnetic fields formed by the magnet devices 226₁ to 226₄ of the sputter units 220₁ to 220₄. When the targets 221₁ to 221₄ of the sputter units 220₁ to 220₄ are brought to a negative potential, the Ar ions collide into the sputtering surfaces 223₁ to 223₄ of the targets 221₁ to 221₄, and Al particles are stricken off.

A portion of the Al particles which have been stricken off from the sputtering surfaces 223₁ to 223₄ of the targets 221₁ to 221₄ of the sputter units 220₁ to 220₄ adheres again to the sputtering surfaces 223₁ to 223₄ of the targets 221₁ to 221₄ of the sputter units 220₁ to 220₄.

The state of the sputter units 220₁ to 220₄ during sputtering is the same. The following explanation uses the sputter unit associated with reference numeral 220₁ as a representative example.

During sputtering, the magnet device 226₁ is moved inside a movement range of which the entire outer periphery of the outer peripheral magnet 227a₁ is inside the space between the one end and the other end of the sputtering surface 223₁, while the target 221₁ is kept stationary without rotating.

When sputtering is continued, the center portion between the one end and the other end of the sputtering surface 223₁ is sputtered and scraped off to a concave shape. The area of the sputtering surface 223₁ which is scraped off by sputtering is referred to as an erosion area. Al particles that adhere again accumulate at the non-erosion areas (i.e., where areas outside of the erosion area on the sputtering surface 223₁ are not sputtered).

The erosion area is scraped off until both ends of the erosion area can be visually confirmed.

Next, the movement range of the magnet device 226₁ is gradually widened and the amount of the part of the outer periphery of the outer peripheral magnet 227a₁ which protrudes to the outside from at least one of the both ends of the sputtering surface 223₁ is gradually increased, while the gas composition during evacuation inside the vacuum chamber 211 is monitored.

As the amount of the part of the outer periphery of the outer peripheral magnet 227a₁ which protrudes to the outside from at least one of the both ends of the sputtering surface 223₁ increases, the horizontal component of the magnetic field on the outer peripheral side surface of at least one of the first and second adhesion-preventing members 225a₁ and 225b₁ increases; and when at least one of the first and second adhesion-preventing members 225a₁ and 225b₁ is scraped off by sputtering, the gas composition inside the vacuum chamber 211 changes during evacuation. When the sputtering of the first and second adhesion-preventing members 225a₁ and 225b₁ has been confirmed by the change in the gas composition during evacuation inside the vacuum chamber 211, the amount of protrusion of the outer periphery of the outer peripheral magnet 227a₁ from both ends of the sputtering surface 223₁ is measured.

In a producing step to be explained later, if at least one of the first and second adhesion-preventing members 225a₁ and 225b₁ is scraped off by sputtering, particles of the first and second adhesion-preventing members 225a₁ and 225b₁ adhere to the surface of the object to be film-formed 231, and the thin film formed on the surface of the object to be film-formed 231 becomes contaminated with impurities. Thus, the amount of protrusion that is measured here is the protruding maximum value.

Next, the application of voltage to the backing plates 222₁ to 222₄ of the sputter units 220₁ to 220₄ is stopped; the introduction of Ar gas from the gas introduction system 213 is stopped; and sputtering is terminated.

The target units 228₁ to 228₄ of the sputter units 220₁ to 220₄ are carried to the outside of the vacuum chamber 211.

At least one of the both ends of the erosion areas of the targets 221₁ to 221₄ of the target units 228₁ to 228₄ which have been carried to the outside of the vacuum chamber 211 is visually confirmed; and the interval between the end of the erosion area which have been scraped off by sputtering on the sputtering surfaces 223₁ to 223₄ and the end of the sputtering surfaces 223₁ to 223₄ are found. Because inside of the interval found here from the outer periphery of the outer peripheral magnets 227a₁ to 227a₄ is scraped off by sputtering, the interval found here is the protruding minimum value.

Next, in the producing step, unused target units 228₁ to 228₄ are carried into the vacuum chamber 211 and attached to the rotating cylinders.

The inside of the vacuum chamber 211 is evacuated by the vacuum evacuation device 212. Subsequently, a vacuum ambience is maintained within the vacuum chamber 211 by continuous evacuation.

The object to be film-formed 231 is mounted on the object holder 232 and carried into the vacuum chamber 211, and then stopped at a position facing the sputtering surfaces 223₁ to 223₄ of the targets 221₁ to 221₄.

Similar to the measuring step, the sputtering gas is introduced from the gas introduction system 213 into the spaces between the object to be film-formed 231 and the targets 221₁ to 221₄ of the sputter units 220₁ to 220₄. AC voltages in the range of 20 kHz to 70 kHz are applied to the backing plates 222₁ to 222₄ of the sputter units 220₁ to 220₄ from the power source device 235; the Ar gas, which is the sputtering gas, between the targets 221₁ to 221₄ of the sputter units 220₁ to 220₄ and the object to be film-formed 231 is plasmatized; and the sputtering surfaces 223₁ to 223₄ of the targets 221₁ to 221₄ of the sputter units 220₁ to 220₄ are sputtered.

A portion of the Al particles which have been stricken off from the sputtering surfaces 223₁ to 223₄ of the targets 221₁ to 221₄ of the sputter units 220₁ to 220₄ adheres to the surface of the object to be film-formed 231; and an Al thin film is formed on the surface of the object to be film-formed 231.

The state of the sputter units 220₁ to 220₄ during sputtering is the same. The following explanation uses the sputter unit associated with reference numeral 220₁ as a representative example.

During sputtering, the magnet device 226₁ of the sputter unit 220₁ is made to repeatedly move between a position where the entire outer periphery of the outer peripheral magnet 227a₁ is on the inside of the space between one end and the other end of the sputtering surface 223₁ of the target 221₁ of the sputter unit 220₁ and another position where a part of the outer periphery of the outer peripheral magnet 227a₁ protrudes out toward the outside from at least one of the both ends of the sputtering surface 223₁.

Because the first and second adhesion-preventing members 225a₁ and 225b₁ are made of an insulating ceramic, the plasma trapped in the magnetic field of the magnet device 226₁ does not disappear even if the plasma is in contact with the first and second adhesion-preventing members 225a₁ and 225b₁; and thus, sputtering can be continued. Therefore, a wider surface area of the sputtering surface 223₁ of the target 221₁ can be sputtered compared to a conventional apparatus.

The target 221₁ is rotated around the center axis line of the target 221₁. When a part of the outer periphery of the outer peripheral magnet 227a₁ protrudes out from both the one end and the other end of the sputtering surface 223₁ by a longer distance than the protruding minimum value found in the measuring step, the entire inside of the space between the one end and the other end of the sputtering surface 223₁ can be scraped off by sputtering.

When the distance which the outer periphery of the outer peripheral magnet 227a₁ protrudes from both the one end and the other end of the sputtering surface 223₁ is limited to a distance which is shorter than the protruding maximum value found in the measuring step, scraping off by sputtering of the first and second adhesion-preventing members 225a₁ and 225b₁ can be prevented.

In reference to FIGS. 7 and 8, sputtering is continued for a predetermined amount of time to form an Al thin film of a predetermined thickness on the surface of the object to be film-formed 231. Subsequently, the application of voltage to the backing plates 222₁ to 222₄ of the sputter units 220₁ to 220₄ is stopped; the introduction of Ar gas from the gas introduction system 213 is stopped; and sputtering is terminated.

The object to be film-formed 231 mounted on the object holder 232 is carried to the outside of the vacuum chamber 211 and sent to a post step. Next, an object to be film-formed 231 upon which a film has not been deposited is placed on the object holder 232 and carried into the vacuum chamber 211; and sputter deposition according to the producing step discussed above is repeated.

In the above explanation of the sputter deposition apparatus 10 of the first embodiment and the sputter deposition apparatus 210 of the second embodiment, a case in which there is a plurality of sputter units is explained. However, the present invention also includes a case in which there is only one sputter unit. In this case, the power source device is electrically connected to the backing plate and the object holder; AC voltages having reverse polarities are applied to the target and the object to be film-formed; electrical discharge is generated between the target and the object to be film-formed; and sputtering gas between the target and the object to be film-formed can be plasmatized.

In the above explanation of both the sputter deposition apparatus 10 of the first embodiment and the sputter deposition apparatus 210 of the second embodiment in reference to FIGS. 2 and 7, the target of each sputter unit and the object to be film-formed are faced toward each other in a state in which they are standing. However, the present invention is not limited to such an arrangement as long as the target of each sputter unit and the object to be film-formed are faced toward each other. Thus, they can be faced toward each other by arranging the object to be film-formed above the target of each sputter unit, or they can be faced toward each other by arranging the object to be film-formed below the target of each sputter unit. If the object to be film-formed is arranged below the target of each sputter unit, particles may fall onto the object to be film-formed, causing the quality of the thin film to deteriorate. Thus, it is preferable to arrange the object to be film-formed above the target of each sputter unit, or face the target of each sputter unit and the object to be film-formed toward each other in a state in which they are standing as in the embodiments explained above.

In the above explanation of both the sputter deposition apparatus 10 of the first embodiment and the sputter deposition apparatus 210 of the second embodiment, an Al; target is used, and an Al thin film is deposited. However, the target of the present invention is not limited to Al, and the target of the present invention also includes a target made of metal materials which is used for wiring of TFT panels (such as, Co, Ni, Mo, Cu, Ti, W alloys, Cu alloys, Ti alloys, and Al alloys), and TCO (Transparent Conductive Oxide) materials (such as, ITO, IGZO, IZO, and AZO, and ASO (Amorphous Semiconductor Oxide) materials).

In FIG. 1, the flat planar shape of the magnet devices 26₁ to 26₄ is represented as a long and narrow shape, but the flat planar shape of the magnet devices 26₁ to 26₄ of the present invention is not limited to a long and narrow shape.

### EXPLANATION OF THE REFERENCE NUMERALS

10, 210 . . . sputter deposition apparatus
11, 211 . . . vacuum chamber
12, 212 . . . vacuum evacuation device
13, 213 . . . gas introduction system
20₁ to 20₄, 220₁ to 220₄ . . . sputter unit
21₁ to 21₄, 221₁ to 221₄ . . . target
25₁ to 25₄ . . . adhesion-preventing member
225a₁ to 225a₄ . . . first adhesion-preventing member
225b₁ to 225b₄ . . . second adhesion-preventing member
26₁ to 26₄, 226₁ to 226₄ . . . magnet device
27a₁, 227a₁ . . . outer peripheral magnet
27b₁, 227b₁ . . . center magnet
29, 229 . . . moving device
31, 231 . . . object to be film-formed
35, 235 . . . power source device

What is claimed is:

1. A sputter deposition apparatus, comprising:
a vacuum chamber;
a vacuum evacuation device evacuating the inside of the vacuum chamber;
a gas introduction system introducing a sputtering gas into the vacuum chamber;
a target having a sputtering surface to be sputtered which is exposed inside the vacuum chamber;
a magnet device arranged on a rear side of the sputtering surface of the target and movable relative to the target; and
a power source device applying a voltage to the target,
wherein the magnet device has a center magnet disposed with an orientation to generate a magnetic field on the sputtering surface and an outer peripheral magnet disposed in a continuous shape on a periphery of the center magnet,
wherein the center magnet and the outer peripheral magnet are disposed in such a manner that the magnetic poles of reverse polarities thereof are oriented toward the sputtering surface,
the sputter deposition apparatus, further comprising:
an adhesion-preventing member made of insulating ceramic disposed at an end of the target,
wherein a surface including the sputtering surface among the surface of the target is discontinuous, so as to surround a periphery of the sputtering surface, and
wherein the magnet device moves between a position where the entire outer periphery of the outer peripheral magnet is on the inside of the inner periphery of the adhesion-preventing member surrounding the periphery of the sputtering surface and another position where a part of the outer periphery of the outer peripheral magnet protrudes to the outer periphery side beyond the inner periphery of the adhesion-preventing member surrounding the periphery of the sputtering surface.

2. The sputter deposition apparatus according to claim 1, further comprising:
a plurality of pairs of the target and the magnet device disposed on the underside of the sputtering surface of the target,
wherein the plurality of targets are arranged in a line spaced apart from each other, the sputtering surfaces being oriented toward an object to be film-formed carried into the vacuum chamber, and
wherein the power source device applies a voltage to at least one of the plurality of targets.

3. The sputter deposition apparatus according to claim 1, wherein the target is a cylindrical shape having the sputtering surface which is a curved surface, and
wherein the magnet device moves parallel to the longitudinal direction of the target.

4. The sputter deposition apparatus according to claim 2, wherein the target is a cylindrical shape having the sputtering surface which is a curved surface, and
wherein the magnet device moves parallel to the longitudinal direction of the target.

5. The sputter deposition apparatus according to claim 2, wherein the magnet device disposed on the rear side of the sputtering surface of at least one of the targets moves between a position where the entire outer periphery of the outer peripheral magnet is on the inside of the inner periphery of the adhesion-preventing member surrounding the periphery of the sputtering surface of the target and another position where a part of the outer periphery of the outer peripheral magnet protrudes out between the outside of the inner periphery of the adhesion-preventing member of the target and the inner periphery of the adhesion-preventing member surrounding the periphery of the sputtering surface of another target adjacent to the target.
